(19) United States
(12) Patent Application Publication
(10) Pub. No.: US 2009/0225804 A1
(43) Pub. Date: Sep. 10, 2009

(54) SEMICONDUCTOR LASER AND METHOD FOR MANUFACTURING THE SAME

(75) Inventors: Yoshifumi Sasahata, Tokyo (JP); Keisuke Matsumoto, Tokyo (JP); Toshitaka Aoyagi, Tokyo (JP); Masahiko Kondow, Hyogo (JP); Masato Morifuji, Hyogo (JP); Hideki Momose, Osaka (JP)

Correspondence Address: LEYDIG VOIT & MAYER, LTD, 700 THIRTEENTH ST. NW, SUITE 300, WASHINGTON, DC, 20005-3960, US

(73) Assignees: MITSUBISHI ELECTRIC CORPORATION, Tokyo (JP); OSAKA UNIVERSITY, Osaka (JP)

(21) Appl. No.: 12/392,453

(22) Filed: Feb. 25, 2009

(30) Foreign Application Priority Data
Mar. 7, 2008 (JP) 2008-058164
Jan. 30, 2009 (JP) 2009-019129

(51) Int. Cl. H01S 5/00; H01L 21/00

(52) U.S. Cl. 372/45.01; 438/38; 438/31; 257/E21.002

(57) ABSTRACT

A semiconductor laser comprises an active section for generating light, and a peripheral section as resonator for producing laser light from the generated light, and includes an InP substrate. The active section has a lower cladding layer formed of AlInAs or AlGaInAs, a core layer including an active layer formed of AlGaInAs or InGaAsP, and an upper cladding layer formed of AlInAs or AlGaInAs. The peripheral section has a first cladding layer formed by oxidizing AlInAs or AlGaInAs, a core layer, and a second clad layer formed by oxidizing AlInAs or AlGaInAs, and a two-dimensional photonic crystal defined by an array of regularly spaced apart holes the peripheral section.

### BACKGROUND OF THE INVENTION

1. Field of the Invention

The present invention relates to a semiconductor laser of a current injection type having an active section for generating light, and a peripheral section of a resonator for obtaining laser beams from the generated light; and to a method for manufacturing the same. More specifically, the present invention relates to a semiconductor laser that can make the difference in refractive indices between the clad layer and the core layer of the peripheral section large enough for forming a photonic band gap, can lower the resistance of the clad layer in the active section, and can relatively easily manufacture a semiconductor laser of wavelengths of 1.3 μm and 1.55 μm.

2. Background Art

Although the speed and capacity of optical communications can be further enhanced by wavelength multiplexing transmission, a wavelength filter, which is a major part of the optical module for wavelength multiplexing transmission is expensive. Therefore, optical devices using photonic crystals that can easily fabricate waveguides, wavelength filters, and the like have been studied. In a semiconductor laser of a current injection type formed in a two-dimensional photonic crystal, outputting light in an in-plane direction and enabling optical coupling with an optical waveguide, a large difference in refractive indices between the core layer and clad layers wherein light is guided and clad layers arranged one above the other is required. If difference in refractive indices is small, optical confinement is weak, loss of light is large, and the semiconductor laser cannot function as a photonic crystal. Therefore, although the air, which has a low refractive index, is often used as clad layers, heat dissipation is poor and mechanical strength is insufficient.

In a certain semiconductor laser of a current injection type formed in a two-dimensional photonic crystal, a semiconductor wherein a current flows is used as a clad layer in the active section that generates light, and an oxide layer of a low refractive index having a large difference from the refractive index of the core layer is used as clad layers in the peripheral section of the resonator for obtaining laser beams from the generated light (for example, refer to Japanese Patent Application Laid-Open No. 2004-296560). An optical integrated circuit having a semiconductor laser of a current injection type and an optical waveguide formed in a two-dimensional photonic crystal has also been reported (for example, refer to Japanese Patent Application Laid-Open No. 2007-194301).

### SUMMARY OF THE INVENTION

Conventionally, AlAs or GaAs was used as a clad layer, and AlAs or GaAs in the peripheral section was oxidized. Thereby, the difference in refractive indices between the clad layers and core layer in the peripheral section could be large enough to form the photonic band gap. However, a current had to be injected via AlAs or GaAs having high resistance (clad layer in the active section).

Conventionally, since GaAs was used as the material for the substrate, and GaInNAs was used as the material for the active layer, the manufacture of a semiconductor laser of wavelengths of 1.3 μm and 1.55 μm to be applied to an optical module for wavelength multiplexing transmission was technically difficult.

Conventionally, the core layer in the peripheral section and the p-type light guiding layer in the active layer were simultaneously grown. For injecting current, p-type GaAs was used as the p-type light guiding layer. Therefore, the loss of light occurred by p-type carriers in the core layer in the peripheral section to be the optical waveguide.

To solve problems as described above, the first object of the present invention is to provide a semiconductor laser that can make the difference in refractive indices between the clad layer and the core layer in the peripheral section large enough to form a photonic band gap, can lower the resistance of the clad layer in the active section, and can relatively easily manufacture a semiconductor laser of wavelengths of 1.3 μm and 1.55 μm; and a method for manufacturing the same.

The second object of the present invention is to provide a semiconductor laser that can reduce loss of light by carriers in the core layer of the peripheral section; and a method for manufacturing the same.

According to one aspect of the present invention, a semiconductor laser comprises an active section for generating light, and a peripheral section of a resonator for obtaining laser beams from the generated light, formed on a same substrate, wherein said substrate is an InP substrate; said active section has a lower clad layer formed of AlInAs or AlGaInAs, a core layer including an active layer formed of AlGaInAs or InGaAsP, and an upper clad layer formed of AlInAs or AlGaInAs; said peripheral section has a first clad layer formed by oxidizing AlInAs or AlGaInAs, a core layer, and a second clad layer formed by oxidizing AlInAs or AlGaInAs; and a two-dimensional photonic crystal wherein a plurality of holes are arrayed in a predetermined distance in said peripheral section.

According to the present invention, the difference in refractive indices between the clad layer and the core layer in the peripheral section can be large enough to form a photonic band gap, can lower the resistance of the clad layer in the active section, and can relatively easily manufacture a semiconductor laser of wavelengths of 1.3 μm and 1.55 μm.

Other and further objects, features and advantages of the invention will appear more fully from the following description.

### BRIEF DESCRIPTION OF THE DRAWINGS

FIG. 1 is a sectional view showing a semiconductor laser according to the first embodiment of the present invention.

FIGS. 2-5 are sectional views for explaining a method of manufacturing a semiconductor laser according to the first embodiment of the present invention.

FIG. 6 is a photonic band diagram wherein energies at the upper end and the lower end of the photonic band gap (two solid lines) and the energy of the light cone (broken line) are plotted by a plane wave expansion method.

FIG. 7 is a sectional view showing a semiconductor laser according to the second embodiment of the present invention.

FIGS. 8-12 are sectional views for explaining a method of manufacturing a semiconductor laser according to the second embodiment of the present invention.

FIG. 13 is a conceptual diagram showing an optical waveguide optically coupled with a semiconductor laser using a two-dimensional photonic crystal.

FIG. 14 is a conceptual diagram showing an integrated optical circuit using a semiconductor laser and an optical waveguide according to the third embodiment of the present invention.

FIG. 15 is a conceptual diagram showing an integrated optical circuit using a semiconductor laser and an optical waveguide according to the fourth embodiment of the present invention.

FIG. 16 is a sectional view showing a semiconductor laser according to the fifth embodiment of the present invention.

FIG. 17 is a conceptual diagram of a cut surface in the AlInAsOₓ clad layer of an integrated optical circuit using a semiconductor laser and an optical waveguide according to the sixth embodiment of the present invention.

### DETAILED DESCRIPTION OF THE PREFERRED EMBODIMENTS

### First Embodiment

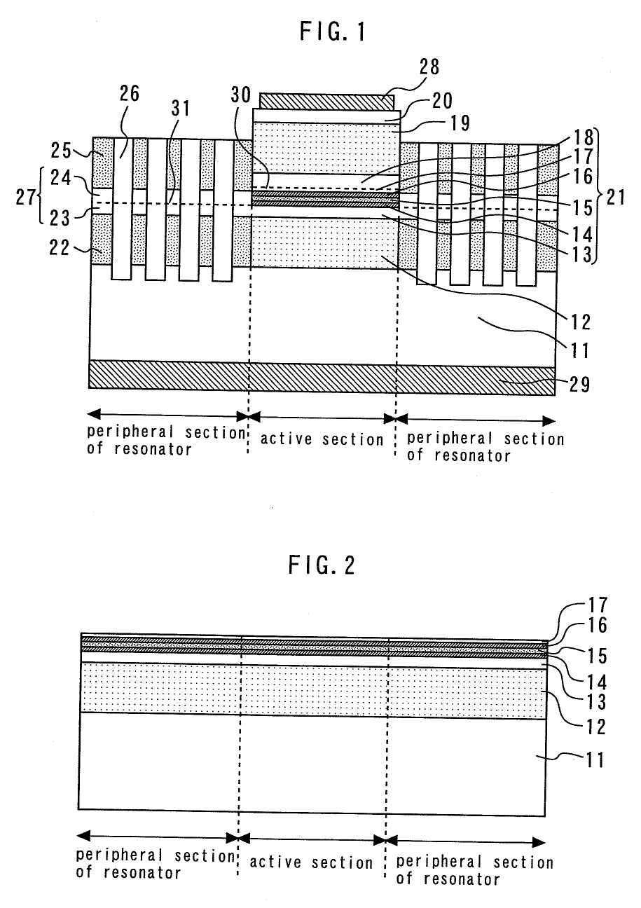

FIG. 1 is a sectional view showing a semiconductor laser according to the first embodiment of the present invention. The semiconductor laser is a semiconductor laser of a current injection type wherein the active section for generating light and the peripheral section, which is a resonator for obtaining laser beams from the generated light, are formed on the same substrate. In the first embodiment, the peripheral section has one or more set of reflective mirrors.

In the active section, an n-type Al_{0.48}In_{0.52}As clad layer 12, an n-type InP light guiding layer 13, an n-type AlGaInAs light guiding layer 14, an undoped AlGaInAs strained quantum well active layer 15, a p-type AlGaInAs light guiding layer 16, p-type InP light guiding layers 17 and 18, a p-type Al_{0.48}In_{0.52}As clad layer 19, and a p-type InGaAs contact layer 20 are sequentially formed on an n-type InP substrate 11.

Here, the n-type InP substrate 11 has an n-type impurity concentration of 1×10¹⁸ cm⁻³, and a thickness of 300 μm. The n-type Al_{0.48}In_{0.52}As clad layer 12 has an n-type impurity concentration of 1×10¹⁸ cm⁻³, and a thickness of 1.5 μm. The n-type InP light guiding layer 13 has an n-type impurity concentration of 1×10¹⁸ cm⁻³, and a thickness of 0.15 μm. The n-type AlGaInAs light guiding layer 14 has an n-type impurity concentration of 1×10¹⁸ cm⁻³, and a thickness of 0.05 μm. The undoped AlGaInAs strained quantum well active layer 15 has a band gap of effectively 0.8 eV, and a thickness of 0.04 μm. The p-type AlGaInAs light guiding layer 16 has a p-type impurity concentration of 5×10¹⁷ cm⁻³, and a thickness of 0.05 μm. The p-type InP light guiding layers 17 and 18 have a p-type impurity concentration of 5×10¹⁷ cm⁻³, and a thickness of 0.15 μm. The p-type Al_{0.48}In_{0.52}As clad layer 19 has a p-type impurity concentration of 1×10¹⁸ cm⁻³, and a thickness of 1.5 μm. The p-type InGaAs contact layer 20 has a p-type impurity concentration of 1×10¹⁹ cm⁻³, and a thickness of 0.3 μm.

The core layer 21 in the active section has the n-type InP light guiding layer 13, the n-type AlGaInAs light guiding layer 14, the undoped AlGaInAs strained quantum well active layer 15, the p-type AlGaInAs light guiding layer 16, and the p-type InP light guiding layers 17 and 18 as described above.

In the peripheral section, an AlInAsO, clad layer 22 formed by oxidizing the n-type Al_{0.48}In_{0.52}As clad layer 12, an n-type InP core layer 23, a p-type InP core layer 24, and an AlInAsOₓ clad layer 25 formed by oxidizing the p-type Al_{0.48}In_{0.52}As clad layer 19 are sequentially formed on the n-type InP substrate 11. In the peripheral section, a triangle lattice-shaped two-dimensional photonic crystal, wherein a plurality of holes 26 are arrayed in a predetermined distance, is also formed.

Here, the n-type InP core layer 23 has an n-type impurity concentration of 1×10¹⁸ cm⁻³, and the p-type InP core layer 24 has a p-type impurity concentration of 5×10¹⁷ cm⁻³. The total thickness of the n-type InP core layer 23 and the p-type InP core layer 24 is 280 nm. The array distance of the holes 26 is 0.4 μm, and the diameter of the holes 26 is 0.24 μm.

The core layer 27 in the peripheral section has the n-type InP core layer 23 and the p-type InP core layer 24. A p-side electrode 28 is formed on the p-type InGaAs contact layer 20, and an n-side electrode 29 is formed on the back face of the n-type InP substrate 11. The reference numerals 30 and 31 denote regrown interfaces.

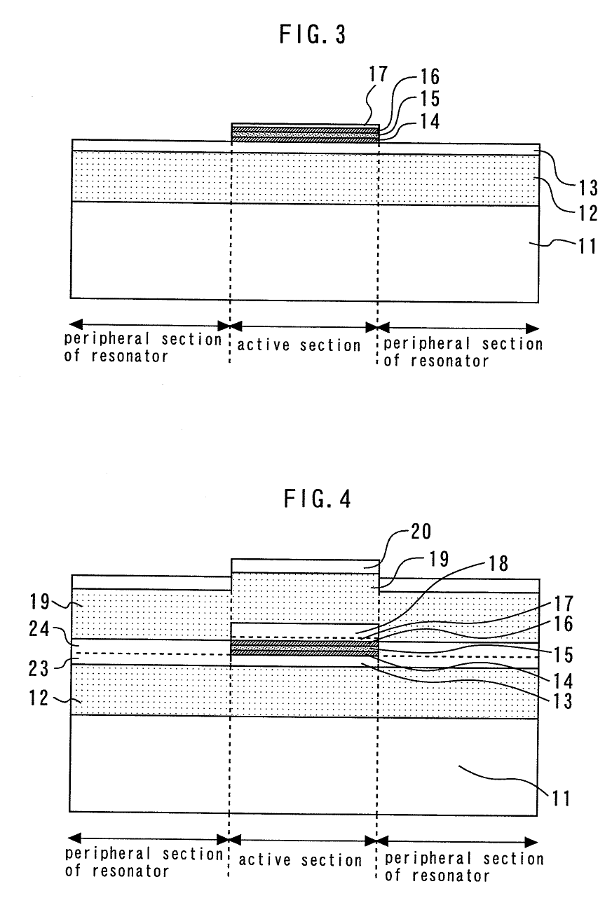

A method for manufacturing a semiconductor laser according to the first embodiment will be described. First, as shown in FIG. 2, the n-type Al_{0.48}In_{0.52}As clad layer 12, the n-type InP light guiding layer 13, the n-type AlGaInAs light guiding layer 14, the undoped AlGaInAs strained quantum well active layer 15, the p-type AlGaInAs light guiding layer 16, and the p-type InP light guiding layer 17 are sequentially formed on the n-type InP substrate 11. Here, the p-type InP light guiding layer 17 functions as a cap layer for preventing the oxidation of the p-type AlGaInAs light guiding layer 16.

Next, as shown in FIG. 3, in the state wherein the active section is coated with a resist (not shown) by photolithography, the p-type InP light guiding layer 17, the p-type AlGaInAs light guiding layer 16, the undoped AlGaInAs strained quantum well active layer 15, and the n-type AlGaInAs light guiding layer 14 are etched in the peripheral section. Here, the depth of etching is about 160 nm.

Next, as shown in FIG. 4, the p-type InP light guiding layer 18, the p-type Al_{0.48}In_{0.52}As clad layer 19, and the p-type InGaAs contact layer 20 are sequentially formed. Here, the n-type InP light guiding layer 13 and the p-type InP light guiding layer 18 in the peripheral section correspond to the n-type InP core layer 23 and the p-type InP core layer 24, respectively.

Next, as shown in FIG. 5, the p-type InGaAs contact layer 20 on the area other than the active section is etched off. Then, by photolithography and dry etching to the upper portion of the n-type InP substrate 11, the plurality of holes 26 are formed in the peripheral section in a predetermined distance to form a triangle lattice-shaped two-dimension photonic crystal.

Next, the n-type Al_{0.48}In_{0.52}As clad layer 12 and the p-type Al_{0.48}In_{0.52}As clad layer 19 in the peripheral section are selectively oxidized by a distance of about 0.1 μm through the plurality of holes 26 to form AlInAsOₓ clad layers 22 and 25 as shown in FIG. 1. Then, the p-side electrode 28 is formed on the p-type InGaAs contact layer 20, and the n-side electrode 29 is formed on the back face of the n-type InP substrate 11. By the above process, a semiconductor laser according to the first embodiment is manufactured.

The refractive index of the oxidized AlInAs (AlInAsOₓ) is 2.3 to 2.5 (refer to Paragraph 0033 of Japanese Patent Application Laid-Open No. 2001-350039). Therefore, by using the oxidized AlInAs as the clad layer of the peripheral section, the difference in the refractive indices between the clad layer and the core layer in the peripheral section can be large enough for forming the photonic band gap.

By using AlInAs as the clad layer of the active section, the resistance can be lowered compared with the case when AlAs or GaAs is used. The oxidation rate of AlInAs much depends on film thickness, and does not depend on Al composition within the range between 0.48 and 0.7. For example, when the oxidation temperature is 500° C. and the film thickness is 100 nm, the oxidation rate of AlInAs is 0.5 μm/min^{1/2} (refer to Furukawa Electric Co., LTD. News Release No. 107). Therefore, since AlInAs can be selectively oxidized in the same manner as AlAs or GaAs, the clad layer in the peripheral section can be formed by oxidizing the AlInAs layer.

By using InP as the material for the substrate, and AlGaInAs as the material for the active layer, a semiconductor laser of wavelengths of 1.3 μm and 1.55 μm can be relatively easily manufactured. In this case, device characteristics more excellent in temperature characteristics can be expected than using InGaAsP, which is one of ordinary InP-based materials.

If InP is used as a material for the substrate, AlGaInAs is used as a material for the active layer and the light guiding layer, and AlInAs or AlGaInAs is used as a material for the clad layer, since the switching of As and P is not required, continuous growth can be performed, and a high-quality crystal can be obtained.

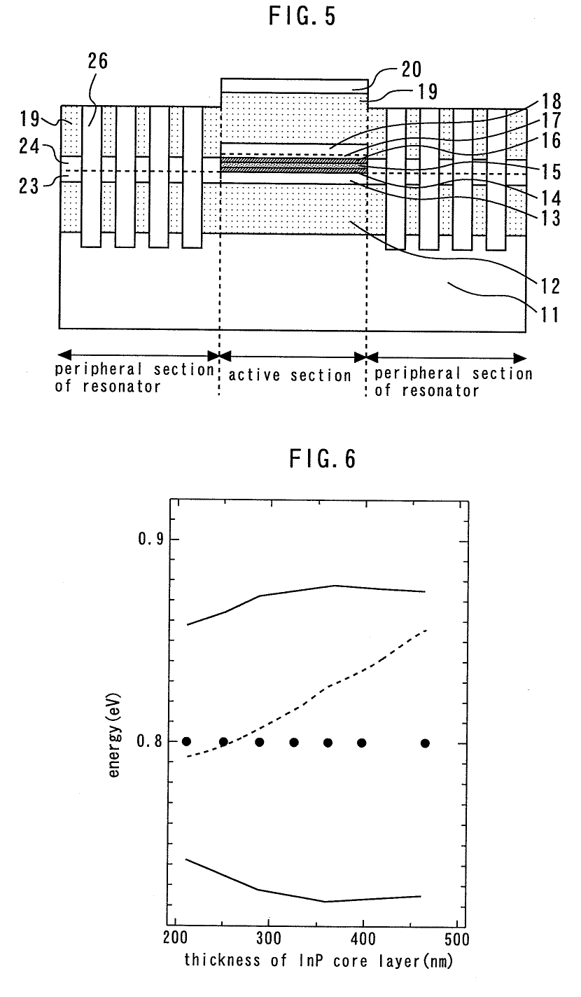

FIG. 6 is a photonic band diagram wherein energies at the upper end and the lower end of the photonic band gap (two solid lines) and the energy of the light cone (broken line) are plotted by a plane wave expansion method. Here, a lattice constant was selected so that the energy at the center point (dots) of the photonic band gap became 0.8 eV (1.55 μm), the clad layer was assumed to be sufficiently thick, and the core layer and the clad layer were assumed to be an InP layer of a refractive index of 3.4 and an AlInAs oxide (AlInAsOₓ) layer, respectively, to calculate. Here, light in the higher energy side than the energy of the light cone leaks for the core layer, the defect level in the vicinity of the center point of the photonic band gap must be in the lower energy side than the energy of the light cone. Therefore, it is known from the result of calculation that the thickness of the InP core layer must be 280 nm or more. Specifically, the thickness of the InP core layer must be at least 70% the array distance of the plurality of holes.

Therefore, the thickness of each of the n-type Al_{0.48}In_{0.52}As clad layer 12 and the p-type Al_{0.48}In_{0.52}As clad layer 19 is made to be 500 nm or more, and the thickness of the core layer 27 in the peripheral section (total thickness of the n-type InP core layer 23 and the p-type InP core layer 24) is made to be at least 280 nm, or at least 70% the array distance of the plurality of holes 26. Thereby, the leakage of light form the core layer can be prevented.

Although the n-type Al_{0.48}In_{0.52}As clad layer 12 and the p-type Al_{0.48}In_{0.52}As clad layer 19 are composed of AlInAs, the present invention is not limited thereto, but AlGaInAs can also be used. In this case, the clad layers 22 and 25 of the peripheral section are formed by oxidizing AlGaInAs. Then, the clad layers 22 and 25 are formed by oxidizing AlInAs or AlGaInAs. The clad layers 22 and 25 can be formed by oxidizing the material which is different from the material of the clad layers 12 and 19 of the active section. Although the undoped AlGaInAs strained quantum well active layer 15 is composed of AlGaInAs, the present invention is not limited thereto, but InGaAsP can also be used.

By changing the wave length of the resonator, or by providing an electrode to change the refractive index when current is injected in addition to the electrode for laser oscillation, the oscillation wavelength can be changed. Furthermore, by forming an optical waveguide in the two-dimensional photonic crystal, the optical waveguide and the semiconductor laser of the current injection type can be integrally formed on the same substrate.

InGaAsP can be used as the core layer in the peripheral section, and AlInAs can be used as the light guiding layer. The thicknesses of respective layers are not limited to the thicknesses in the first embodiment. For example, the number of wells in the active layer portion can be increased (to 2 to 15 wells), and the thicknesses of about 30 to 200 nm can also be used. The depth of etching is also changed corresponding to the thicknesses of the layers.

### Second Embodiment

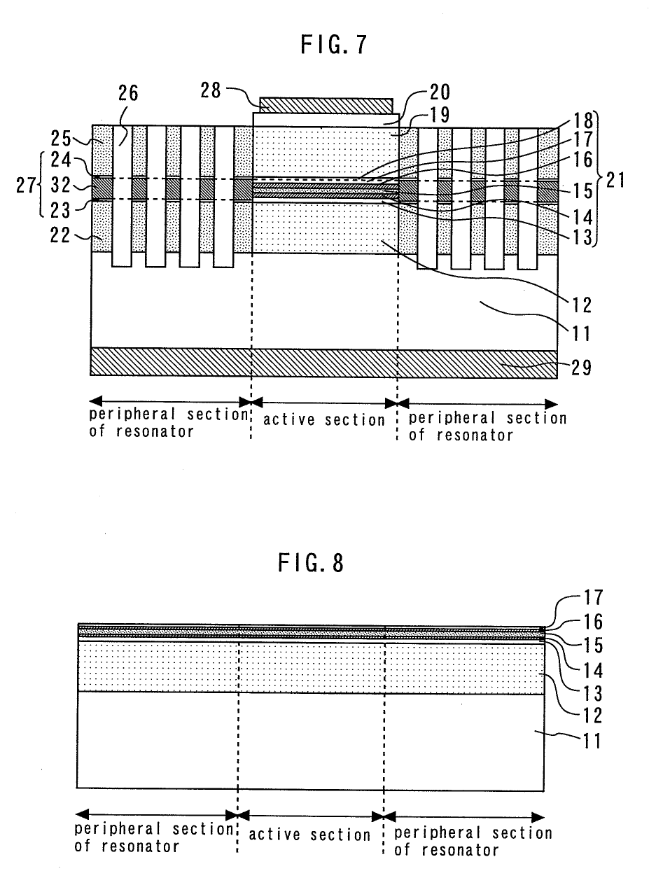

FIG. 7 is a sectional view showing a semiconductor laser according to the second embodiment of the present invention. The core layer 27 in the peripheral section has an undoped InP core layer 32. Other configurations are identical to the configurations of the first embodiment.

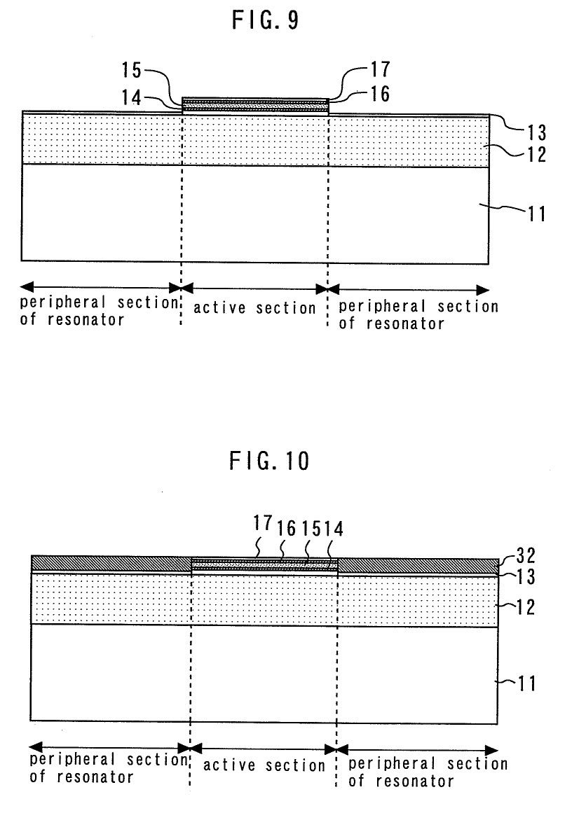

A method for manufacturing a semiconductor laser according to the second embodiment will be described. First, as shown in FIG. 8, the n-type Al_{0.48}In_{0.52}As clad layer 12, the n-type InP light guiding layer 13, the n-type AlGaInAs light guiding layer 14, the undoped AlGaInAs strained quantum well active layer 15, the p-type AlGaInAs light guiding layer 16, and the p-type InP light guiding layer 17 are sequentially formed on the n-type InP substrate 11. Here, the p-type InP light guiding layer 17 functions as a cap layer for preventing the oxidation of the p-type AlGaInAs light guiding layer 16.

Next, as shown in FIG. 9, in the state wherein the active section is coated with a resist (not shown) by photolithography, the p-type InP light guiding layer 17, the p-type AlGaInAs light guiding layer 16, the undoped AlGaInAs strained quantum well active layer 15, the n-type AlGaInAs light guiding layer 14, and the n-type InP light guiding layer are etched in the peripheral section. Here, the depth of etching is about 350 nm.

Next, as shown in FIG. 10, the undoped InP core layer 32 is formed on the peripheral section. Then, as shown in FIG. 11, the p-type InP light guiding layer 18, the p-type Al_{0.48}In_{0.52}As clad layer 19, and the p-type InGaAs contact layer 20 are sequentially formed. Here, the n-type InP light guiding layer 13 and the p-type InP light guiding layer 18 in the peripheral section correspond to the n-type InP core layer 23 and the p-type InP core layer 24, respectively.

Next, as shown in FIG. 12, the p-type InGaAs contact layer 20 on the area other than the active section is etched off. Then, by photolithography and dry etching to the upper portion of the n-type InP substrate 11, the plurality of holes 26 are formed in the peripheral section in a predetermined distance to form a triangle lattice-shaped two-dimension photonic crystal.

Next, the n-type Al_{0.48}In_{0.52}As clad layer 12 and the p-type Al_{0.48}In_{0.52}As clad layer 19 in the peripheral section are selectively oxidized by a distance of about 0.1 μm through the plurality of holes 26 to form AlInAsOₓ clad layers 22 and 25 as shown in FIG. 7. Then, the p-side electrode 28 is formed on the p-type InGaAs contact layer 20, and the n-side electrode 29 is formed on the back face of the n-type InP substrate 11. By the above process, a semiconductor laser according to the second embodiment is manufactured.

By forming the undoped InP core layer 32 as the core layer 27 in the peripheral section, the loss of light by carriers can be reduced in the core layer 27 in the peripheral section, which becomes an optical waveguide. Furthermore, since the lowering of carrier concentration in the p-type InP light guiding layers 17 and 18 is not required, the concentration can be, for example, 1×10¹⁸ cm⁻³. Thereby, the resistance of the clad layer in the active section can be further lowered.

Equivalent to the first embodiment, the thickness of each of the n-type Al_{0.48}In_{0.52}As clad layer 12 and the p-type Al_{0.48}In_{0.52}As clad layer 19 is made to be 500 nm or more, and the thickness of the core layer 27 in the peripheral section (thickness of the undoped InP core layer 32) is made to be at least 280 nm. Thereby, the leakage of light form the core layer can be prevented.

### Third Embodiment

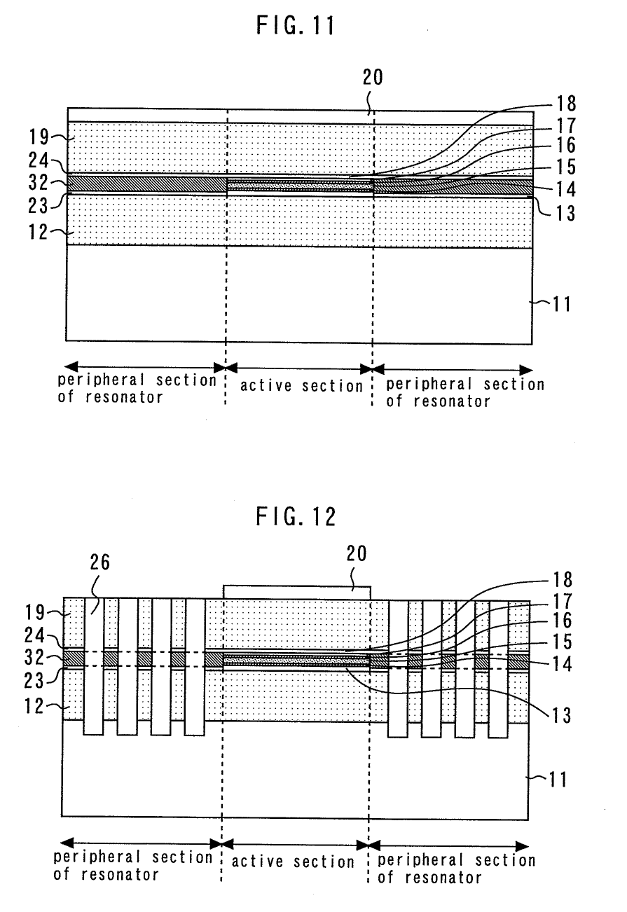

FIG. 13 is a conceptual diagram showing an optical waveguide optically coupled with a semiconductor laser using a two-dimensional photonic crystal. A semiconductor laser 34 and a waveguide 35 are formed in a two-dimensional photonic crystal 33. The semiconductor laser 34 corresponds to the active section according to the first or second embodiment. Resonance occurs in the semiconductor laser 34 and the laser oscillates, and the output light of the semiconductor laser 34 can be taken out of the waveguide 35. In addition, since the wavelength of the standing wave is changed by changing the length of the optical resonator in the semiconductor laser 34, the oscillation wavelength can be changed.

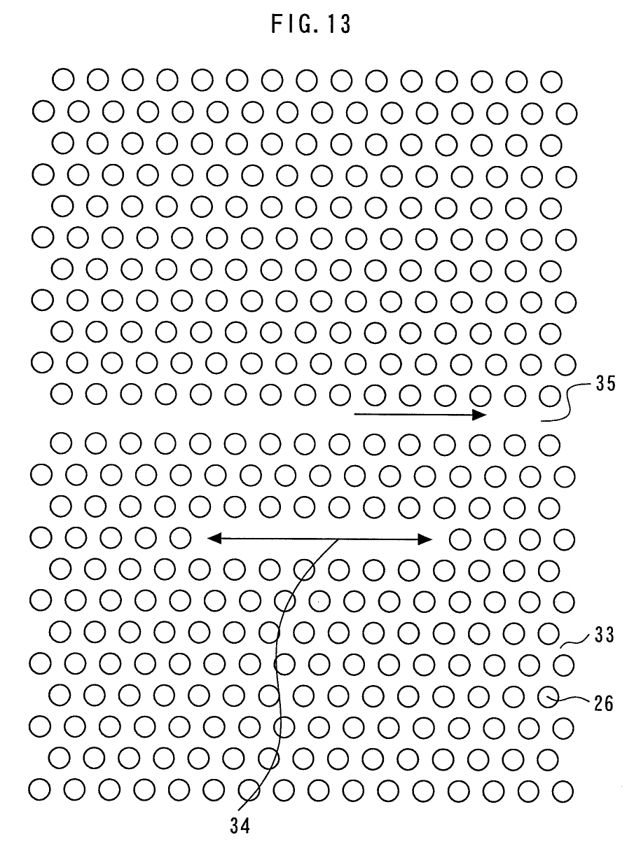

FIG. 14 is a conceptual diagram showing an integrated optical circuit using a semiconductor laser and an optical waveguide according to the third embodiment of the present invention. Semiconductor lasers 34a, 34b, 34c and 34d, and a waveguide 35 are integrated in a two-dimensional photonic crystal 33. The semiconductor lasers 34a, 34b, 34c and 34d correspond to the active section according to the first or second embodiment. However, the lengths of respective optical resonators are different. Thereby, four kinds of light having different wavelengths can be taken out of one waveguide 35.

### Fourth Embodiment

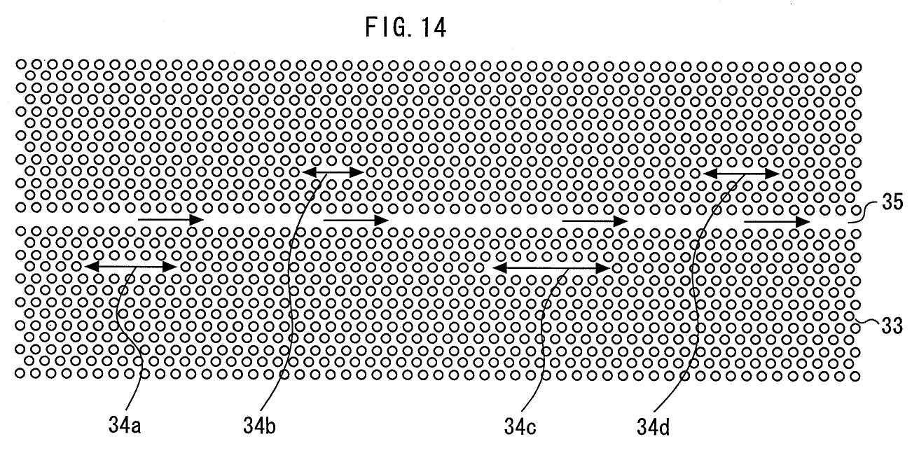

FIG. 15 is a conceptual diagram showing an integrated optical circuit using a semiconductor laser and an optical waveguide according to the fourth embodiment of the present invention. In the semiconductor lasers 34a, 34b, 34c and 34d, in addition to electrodes for laser oscillation, electrodes 36a, 36b, 36c and 36d for changing the oscillation wavelengths are formed in the active section, respectively. Other configurations are same as the configurations of the third embodiment. Since refractive indices change to change the length of resonators by supplying current to the electrodes 36a, 36b, 36c and 36d, the oscillation wavelengths can be changed.

### Fifth Embodiment

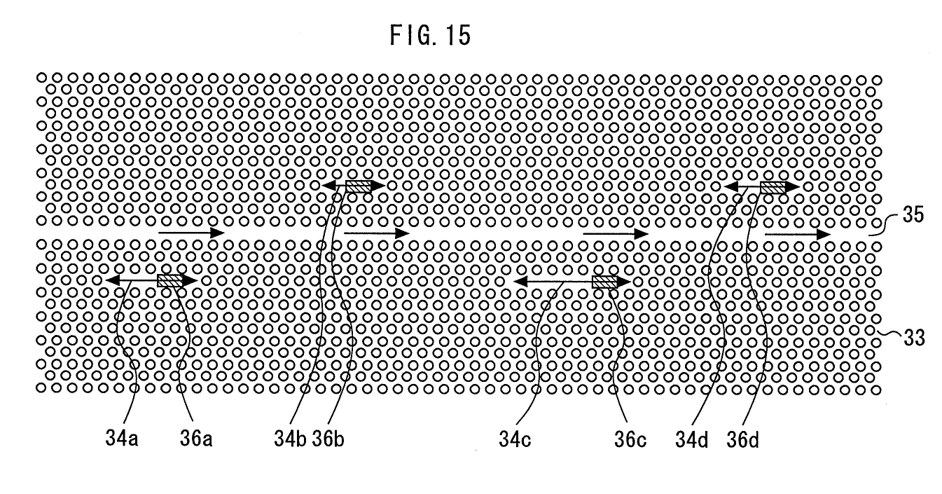

FIG. 16 is a sectional view showing a semiconductor laser according to the fifth embodiment of the present invention. The p-type Al_{0.48}In_{0.52}As clad layer 19 in the second embodiment is replaced by a p-type Al_{0.48}In_{0.52}As clad layer 37, a p-type Ga_{0.7}In_{0.3}As tunnel coupling layer 38, an n-type Ga_{0.7}In_{0.3}As tunnel coupling layer 39, and an n-type Al_{0.48}In_{0.52}As clad layer 40. The p-type InGaAs contact layer 20 and the upper electrode 28 in the second embodiment are replaced by an n-type InGaAs contact layer 41 and an n-type upper electrode 42 corresponding to the n-type. Other configurations and manufacturing methods are same as those in the second embodiment.

Both the p-type Ga_{0.7}In_{0.3}As tunnel coupling layer 38 and the n-type Ga_{0.7}In_{0.3}As tunnel coupling layer 39 have a thickness of 10 nm, and a carrier concentration of 1×10²⁰ cm⁻³. Since these films are ultra-thin films having ultra-high carrier concentrations, the conductivity type can be changed from p-type to n-type at a low resistance. The p-type Al_{0.48}In_{0.52}As clad layer 37 has a thickness of 0.08 μm, and a carrier concentration of 1×10¹⁸ cm⁻³. The n-type Al_{0.48}In_{0.52}As clad layer 40 has a thickness of 1.4 μm, and a carrier concentration of 1×10¹⁸ cm⁻³.

Although the non-oxidized p-type Ga_{0.7}In_{0.3}As tunnel coupling layer 38, and n-type Ga_{0.7}In_{0.3}As tunnel coupling layer 39 are present on the upper clad layer in the peripheral section, these are ultra-thin films, and do not cause the loss of light. The AlInAsOₓ clad layer 25 in the peripheral section is formed by selectively oxidizing the p-type Al_{0.48}In_{0.52}As clad layer 37 and the n-type Al_{0.48}In_{0.52}As clad layer 40.

By introducing the tunnel junction in the semiconductor laser as described above, the conductivity type of two electrodes for injecting current and the semiconductor layers contacting thereto can be n-type. Since the mobility of n-type Al_{0.48}In_{0.52}As is dramatically higher than the mobility of p-type Al_{0.48}In_{0.52}As, resistance is lowered. Therefore, the resistance of the upper clad layer in the active section, and furthermore, the entire laser element can be significantly lowered. As a result, many advantages, such as the suppression of heat generation of the element and the possibility of high-speed operations, can be obtained.

In the fifth embodiment, although the tunnel junction is formed in the clad layer, the tunnel junction can be alternatively formed in the core layer.

### Sixth Embodiment

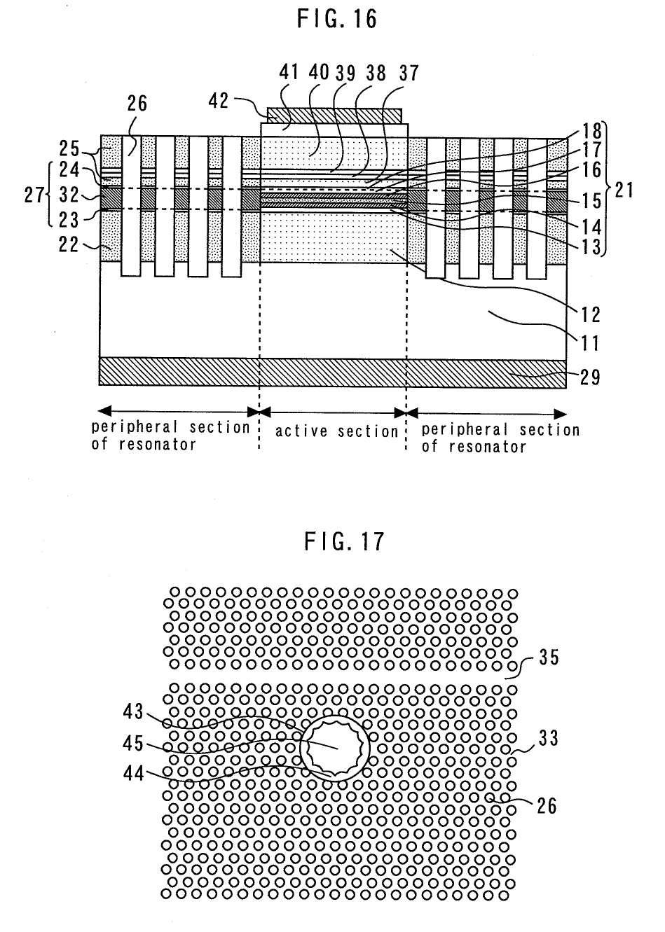

FIG. 17 is a conceptual diagram of a cut surface in the AlInAsOₓ clad layer of an integrated optical circuit using a semiconductor laser and an optical waveguide according to the sixth embodiment of the present invention.

A resonator 43 of the semiconductor laser and the waveguide 35 are formed in a two-dimensional photonic crystal 33 wherein a plurality of holes 26 are arrayed in a predetermined distance. The resonator 43 corresponds to the active section of the semiconductor laser according to the first, second or fifth embodiment.

In the AlInAsOₓ clad layer of the resonator 43, a selectively oxidized AlInAsOₓ portion 44 and a non-oxidized AlInAs portion 45 are present. The width of the selectively oxidized AlInAsOₓ portion 44 is made to be 230 nm.

To make the oscillation wavelength of the laser in the 1.3 μm band, the effective band gap of the strained quantum well active layer is made to be 0.95 eV, the array distance of the holes 26 in the two-dimensional photonic crystal 33 is made to be 0.32 μm, and the diameter of each hole 26 is made to be 0.19 μm.

In the first and second embodiments, the thickness of the core layer in the selectively oxidized portion must be at least 280 μm, specifically, at least 70% the array distance of the holes 26. While in the sixth embodiment, the thickness of the core layer in the selectively oxidized portion is 256 μm, which is 80% the array distance of the holes 26.

The shape of the resonator 43 in the plane of the two-dimensional photonic crystal 33 is circular, and there are no parallel portions. However, laser oscillation occurs in the whispering gallery mode wherein standing waves are generated in the peripheral section of the resonator 43. Therefore, no so-called reflection mirror is required. Specifically, the resonator 43 surrounded by the two-dimensional photonic crystal 33 does not necessarily require parallel portions, and the shape is not limited as long as the resonance characteristics are sufficiently high.

The output beams of the semiconductor laser can be taken out of the waveguide 35 in the same manner as the third or forth embodiment of the present invention. Since the wavelength of the standing waves in changed by changing the size of the resonator 43 of the semiconductor laser, the oscillation wavelength can be changed. Therefore, the semiconductor laser according to the sixth embodiment can be applied to integrated optical circuits in the same manner as the third or forth embodiment.

In the sixth embodiment, since the cut surface area of the resonator 43 can be enlarged, the resistance of the laser element can be lowered. In addition, since the oxidation distance of the AlInAsO, clad layer is large, the entire portion of the waveguide 35 is selectively oxidized. Therefore, ineffective current wherein the current injected from the electrodes leaks into the waveguide 35 can be suppressed.

Obviously many modifications and variations of the present invention are possible in the light of the above teachings. It is therefore to be understood that within the scope of the appended claims the invention may be practiced otherwise than as specifically described.

The entire disclosure of a Japanese Patent Application No. 2008-58164, filed on Mar. 7, 2008 and a Japanese Patent Application No. 2009-19129, filed on Jan. 30, 2009 including specification, claims, drawings and summary, on which the Convention priority of the present application is based, are incorporated herein by reference in its entirety.

1. A semiconductor laser comprising:
InP substrate;
an active section in which light is generated, supported by the InP substrate, and including a lowers cladding layer of AlInAs or AlGaInAs, a core layer including an active layer of AlGaInAs or InGaAsP, and an upper cladding layer of AlInAs or AlGaInAs;
a resonator supported by the InP substrate and in which the light generated in the active section resonates to produce laser light and comprising a peripheral section including a first cladding layer of oxidized AlInAs or AlGaInAs, a core layer, and a second cladding layer of oxidized AlInAs or AlGaInAs, and including a two-dimensional photonic crystal defined by an array of regularly spaced apart holes in the peripheral section.

2. The semiconductor laser according to claim 1, wherein
the core layer of the active section further includes a light guiding layer of InP or AlGaInAs of a first conductivity type and a light guiding layer of InP or AlGaInAs of a second conductivity type; and
the core layer of the peripheral section includes a first core layer of InP of a first conductivity type and a second core layer of InP of a second conductivity type.

3. The semiconductor laser according to claim 1, wherein the core layer of the peripheral section includes an undoped InP core layer.

4. The semiconductor laser according to claim 1, wherein
each of the first and second cladding layers in the peripheral section is at least 500 nm thick, and
each of the first and second core layers in the peripheral section is at least 280 nm thick.

5. The semiconductor laser according to claim 1, wherein
each of the first and second cladding layers in the peripheral section is at least 500 nm thick, and
the core layer in the peripheral section has a thickness that is at least 70% of the distance between the holes, in the array of holes of the photonic crystal.

6. The semiconductor laser according to claim 1, including a first electrode and a second electrode contacting n-type layers of the semiconductor laser for injecting current.

7. The semiconductor laser according to claim 6, wherein
the substrate and the lower cladding layer are n-type;
the upper clad layer is p-type;
the active section further includes a p-type tunnel coupling layer, an n-type tunnel coupling layer, an n-type cladding layer, and an n-type contact layer, sequentially arranged on the upper cladding layer;
the first electrode is coupled to the substrate: and
the second electrode is coupled to the n-type contact layer.

8. The semiconductor laser according to claim 1, wherein the peripheral section includes at least one set of reflection mirrors.

9. The semiconductor laser according to claim 1, wherein resonator has a shape in a plane of the two-dimensional photonic crystal that is free of parallel portions.

10. The semiconductor laser according to claim 1, wherein the resonator has a circular shape in a plane of the two-dimensional photonic crystal.

11. The semiconductor laser according to claim 1, including an optical waveguide in the two-dimensional photonic crystal.

12. A method for manufacturing a semiconductor laser including an active section for generating light, and a resonator including a peripheral section for producing laser light from the light generated, comprising:
sequentially forming a lower cladding layer of AlInAs or AlGaInAs, a lower InP light guiding layer, an active layer of AlGaInAs or InGaAsP, and a first upper InP light guiding layers on an InP substrate;
etching the first upper InP light guiding layer and the active layer in the peripheral section;
sequentially forming a second upper InP light guiding layer and an upper cladding layer of AlInAs or AlGaInAs, after the etching;
forming a plurality of holes in the upper cladding layer, the second upper InP light guiding layer, the lower InP light guiding layer, and the lower cladding layer, spaced apart in a regular array, at a predetermined
spacing in the peripheral section to form a two-dimensional photonic crystal; and
oxidizing the lower cladding layer and the upper cladding layer in the peripheral section through the plurality of holes.

13. The method for manufacturing a semiconductor laser according to claim 12, wherein
each of the lower cladding layer and upper cladding layer in the peripheral section is at least 500 nm thick; and
total thickness of the lower InP light guiding layer and the second upper InP light guiding layer in the peripheral section is at least 280 nm.

14. The method for manufacturing a semiconductor laser according to claim 12, wherein
each of the lower cladding layer and the upper cladding layer in the peripheral section is at least 500 mn thick; and
total thickness of the lower InP light guiding layer and the second upper InP light guiding layer in the peripheral section is at least 70% of the predetermined spacing of the holes.

15. A method for manufacturing a semiconductor laser including an active section for generating light, and a resonator including a peripheral section for producing laser light from the light generated, comprising:
sequentially forming a lower cladding layer of AlInAs or AlGaInAs, a lower InP light guiding layer, an active layer of AlGaInAs or InGaAsP, and a first upper InP light guiding layer, on an InP substrate;
etching the upper InP light guiding layer, the active layer, and the lower InP light guiding layer in the peripheral section;
forming an undoped InP core layer in the peripheral section, after the etching;
forming an upper cladding layer of AlInAs or AlGaInAs, after forming the undoped InP core layer;
forming a plurality of holes in the upper cladding layer, the undoped InP core layer, and the lower cladding layer in a regular array, at a predetermined spacing in the peripheral section to form a two-dimensional photonic crystal; and
oxidizing the lower cladding layer and the upper cladding layer in the peripheral section through the plurality of holes.

16. The method for manufacturing a semiconductor laser according to claim 15, wherein
each of the lower cladding layer and the upper cladding layer in the peripheral section is at least 500 nm thick; and
the undoped InP core layer in the peripheral section is at least 280 nm thick.

17. The method for manufacturing a semiconductor laser according to claim 15, wherein
each of the lower cladding layer and the upper cladding layer in the peripheral section is at least 500 nm thick; and
the undoped InP core layer in the peripheral section has a thickness of at least 70% of the predetermined spacing of the holes.

18. The method for manufacturing a semiconductor laser according to claim 12, wherein the peripheral section has at least one set of reflection mirrors.

19. The method for manufacturing a semiconductor laser according to claim 12, wherein the resonator has a shape in a plane of the two-dimensional photonic crystal that is free of parallel portions.

20. The method for manufacturing a semiconductor laser according to claim 12, wherein the resonator has a circular shape in a plane of the two-dimensional photonic crystal.

21. The method for manufacturing a semiconductor laser according to claim 12, including an optical waveguide in the two-dimensional photonic crystal.
